(19) United States
(12) Patent Application Publication
(10) Pub. No.: US 2026/0211014 A1
(43) Pub. Date: Jul. 23, 2026

(54) ELECTRICITY METER WITH THERMAL PROTECTION

(71) Applicant: Landis+Gyr Technology, Inc., Alpharetta, GA (US)

(72) Inventor: Anibal Diego RAMIREZ, Indianapolis, IN (US)

(21) Appl. No.: 19/138,920

(22) PCT Filed: Dec. 13, 2023
(86) PCT No.: PCT/US2023/083737

§ 371 Date: Jun. 13, 2025

(30) Foreign Application Priority Data
Dec. 15, 2022 (GB) 2218912.0

(51) Int. Cl. G01R 22/06; H02H 5/04

(52) U.S. Cl. CPC G01R 22/068; H02H 5/047

(57) ABSTRACT

An electricity meter (100) for connection to a utility power line and a load via a meter mounting device and for determining power consumption between the utility power line and the load. The electricity meter (100) comprises a baseplate (102) comprising at least one blade (114a-d) configured to couple to a corresponding jaw of the meter mounting device to electrically connect the electricity meter (100) to the utility power line and the load; a service switch (140) operable to enable or disable the electrical connection between the utility power line and the electricity meter (100). The baseplate (102) further comprises a thermal device (126a, 126b) located adjacent to the at least one blade (114a-d) and configured to control the service switch (140) to disable the electrical connection between the utility power line and the electricity meter (100) if a temperature of the thermal device (126a, 126b) exceeds a temperature threshold.

### TECHNICAL FIELD

The invention relates to an electricity meter for connection to a utility power line and a load via a meter mounting device.

### BACKGROUND

Electricity meters, or metering devices, measure electrical energy or power consumption between a utility line and a load in order to determine the amount of electric energy or power consumed by a residence, business or electrically powered device.

In a typical residential installation, the electricity meter is attached to the utility line and the load through a meter mounting device (or meter socket). The electricity meter comprises a baseplate comprising electrical contact(s), specifically blades. The blades connect to corresponding utility power line and load jaws of the meter mounting device to connect the electricity meter to the power line and load respectively and to allow measurement of the load current and load voltage. A significant amount of current flows across the blades of the baseplate when the electricity meter is connected to the meter mounting device.

Typically, in residential installations, the meter mounting device and the electricity meter connected thereto are installed outside, and therefore the jaws of the meter mounting device and the blades of the electricity meter may be exposed to outside conditions (such as extreme temperatures, moisture etc.). Over the service life of the meter mounting device it is not uncommon for the jaws of the meter mounting device to degrade. In some instances, the jaws may degrade to such an extent that non-trivial resistance is introduced at the connection between the jaws of the meter mounting device and the blade(s) of the baseplate of the electricity meter. This may in turn cause temperature increases and overheating of the electricity meter, and in particular the blade(s) and baseplate. Depending on the severity of the degradation, the temperature rise may cause the mechanical integrity of the baseplate, which is typically made of plastic, to be compromised (this may occur at approximately 200° C.). For example, the baseplate may begin to melt or deform, or otherwise suffer structural damage.

In known arrangements, a temperature monitoring or sensing device is incorporated into the electricity meter electronics for monitoring overheating of the electricity meter. However, the electricity meter electronics are typically separated from the contact point between the jaws of the meter mounting device and the blades of the electricity meter by multiple thermal barriers and shrouds, for example by a body of the baseplate and the baseplate shroud. As such, known arrangements are generally not very effective at providing an early detection of overheating and are mainly used to manage the operating temperature(s) of the electricity meter electronics.

Further known arrangements may incorporate an RF arc detector to detect overheating of the electricity meter. While a promising solution, use of RF arc detection methods requires a separate electronics assembly which can be expensive to incorporate.

There exists a need to provide an improved electricity meter capable of early detection of an adverse thermal event at the connection between blades of a baseplate and jaws of a meter mounting device.

### SUMMARY

According to the invention in a first aspect, there is provided an electricity meter for connection to a utility power line and a load via a meter mounting device and for determining power consumption between the utility power line and the load, the electricity meter comprising: a baseplate comprising at least one blade configured to couple to a corresponding jaw of the meter mounting device to electrically connect the electricity meter to the utility power line and the load; a service switch operable to enable or disable the electrical connection between the utility power line and the electricity meter, wherein the baseplate further comprises a thermal device located adjacent to the at least one blade and configured to control the service switch to disable the electrical connection between the utility power line and the electricity meter if a temperature of the thermal device exceeds a temperature threshold.

Optionally, the thermal device is mounted to the baseplate.

Optionally, the electricity meter further comprises a baseplate shroud connected to the baseplate, and wherein the thermal device is located in an internal chamber formed between the baseplate and the baseplate shroud.

Optionally, the service switch is located in the internal chamber.

Optionally, the electricity meter further comprises a conductive body, wherein the at least one blade extends from the conductive body, and the thermal device is located adjacent to the conductive body. Optionally, the thermal device abuts the conductive body.

Optionally, the conductive body is located in the internal chamber and wherein the at least one blade is located externally to the internal chamber.

Optionally, the thermal device forms part of a circuit, and wherein the thermal device is configured to break the circuit when the temperature of the thermal device exceeds the temperature threshold.

Optionally, the service switch is controlled to enable the electrical connection between the utility power line and the electricity meter when the circuit is closed and disable the electrical connection between the utility power line and the electricity meter when the circuit is broken.

Optionally, the electricity meter further comprises electricity meter electronics comprising a microprocessor, and wherein the thermal device forms the circuit with the microprocessor.

Optionally, if the circuit between the microprocessor and the thermal device is broken, the microprocessor is configured to control the service switch to disable the electrical connection between the utility power line and the electricity meter.

Optionally, the electricity meter electronics are separated from the thermal device by the baseplate shroud.

Optionally, the thermal device forms a circuit with the service switch, and wherein the service switch is configured to disable the electrical connection between the utility power line and the electricity meter if the circuit is broken.

Optionally, the baseplate comprises first and second blades, a first thermal device located adjacent to the first blade, and a second thermal device located adjacent to the second blade.

Optionally, the first and second thermal devices are mounted to the baseplate.

Optionally, the thermal device comprises a thermal cut-off fuse or thermal switch.

According to the invention in a further aspect, there is provided a baseplate for an electricity meter, the electricity meter for connection to a utility power line and a load via a meter mounting device and for determining power consumption between the utility power line and the load, the baseplate comprising: at least one blade configured to couple to a corresponding jaw of the meter mounting device to electrically connect the electricity meter to the utility power line and the load; and a thermal device located adjacent to the at least one blade and configured to control a service switch to disable the electrical connection between the utility power line and the electricity meter if a temperature of the thermal device exceeds a temperature threshold.

Optionally, the baseplate further comprises the service switch

### BRIEF DESCRIPTION OF THE DRAWINGS

FIG. 1 shows an exploded view of an exemplary electricity meter;

FIG. 2 shows an exploded view of an exemplary baseplate and baseplate shroud;

FIG. 3 shows a front view of an exemplary baseplate; and

FIG. 4 is a schematic block diagram of an exemplary electricity meter.

### DETAILED DESCRIPTION

Generally disclosed herein is an electricity meter for electrical connection to a utility power line and a load via a meter mounting device. The electricity meter comprises a baseplate comprising at least one blade configured to connect to a utility power line jaw (connected to the utility power line) or a load jaw (connected to the load) of the meter mounting device to electrically connect the electricity meter to the utility power line or the load. The electricity meter further comprises a service switch that can be closed and opened to respectively enable or disable the electrical connection between the utility power line and the electricity meter. The exemplary baseplate of the invention further comprises a thermal device located adjacent to, and/or in close proximity to, the at least one blade. The thermal device is configured to control the service switch to open to disable the electrical connection between the utility power line and the electricity meter if the temperature of the thermal device exceeds a temperature threshold.

The thermal device of the exemplary electricity meter disclosed herein forms part of the baseplate arrangement, and in a specific example, is mounted to a baseplate body of the baseplate. The baseplate body is connectable to a baseplate shroud to form an internal chamber therebetween, and the thermal device is located within the internal chamber. As such, the thermal device of the invention is not thermally isolated from the contact point between the at least one blade and the jaw by multiple internal barriers and shrouds, as is typical in known arrangements. In particular, the thermal device is not separated from the contact point between the at least one blade and the jaw by the baseplate shroud.

By locating the thermal device on the baseplate and in close proximity to the at least one blade, the thermal device experiences temperatures similar to the temperatures experienced by the at least one blade and/or the baseplate body. Temperature increases at the blades and/or baseplate body can therefore be more quickly detected, and as such corrective action (such as disabling the supply of power from the utility power line to the electricity meter) can be taken before catastrophic damage of the baseplate and/or other components of the electricity meter occurs due to overheating.

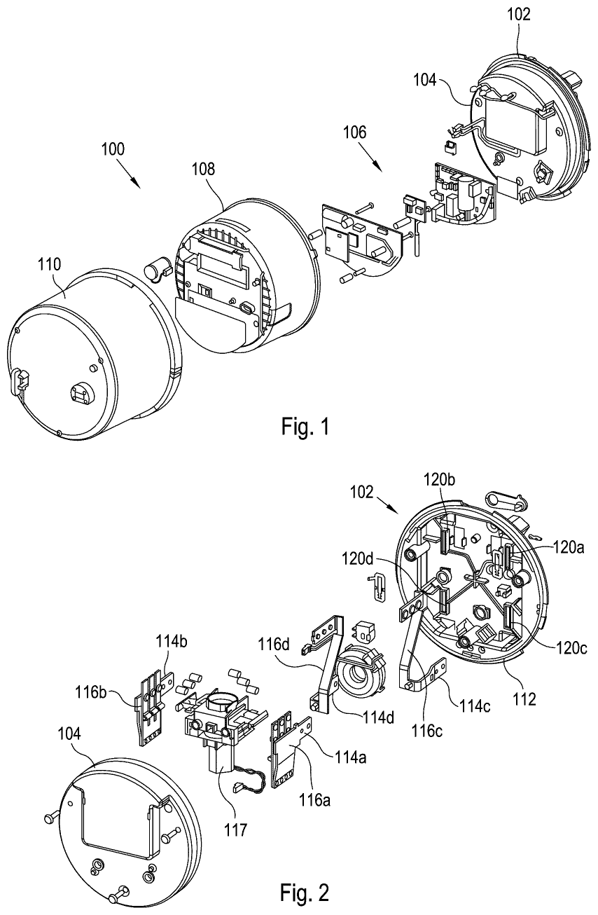

FIG. 1 shows an exploded view of an exemplary electricity meter 100. The exemplary electricity meter 100 is configured for connection to a utility power line and a load via a meter mounting device (not shown). The meter 100 comprises a baseplate 102. The exemplary electricity meter 100 further comprises a baseplate shroud 104, electricity meter electronics 106, an electronics housing 108, and an electricity meter housing 110.

FIG. 2 shows an exploded view of the baseplate 102 and the baseplate shroud 104. The baseplate 102 comprises a baseplate body 112, which may be completely, or at least partially, formed from plastic. The baseplate 102 and the baseplate shroud 104 are connectable to form an internal chamber between the baseplate body 112 and the baseplate shroud 104.

The baseplate 102 comprises blades 114a-d. The baseplate 102 may further comprise current coil arrangements comprising conductive bodies 116a-d. The conductive bodies 116a-d are configured to carry current between respective blades. In the exemplary arrangement shown in FIG. 2, each blade 114a-d is integrally formed with a respective conductive body 116a-d.

In the exemplary arrangement shown in FIG. 2, the conductive body 116a is electrically coupled to the conductive body 116c (for example, via an intermediary component 117) and as such, current can flow between the blades 114a and 114c. Similarly, the conductive body 116b is electrically coupled to the conductive body 116d (for example, via the intermediary component 117) and as such, current can flow between the blades 114b and 114d. The skilled person will appreciate that in alternative arrangements, the respective blades 114a, 114c may be integrally formed with conductive bodies 116a, 116c (i.e. provided as a single component), and the blades 114b, 114d may be integrally formed with the conductive bodies 116b, 116d (i.e. provided as a single component).

The blades 114a-d may extend through respective apertures 120a-d formed in the baseplate body 112 such that the blades 114a-d are disposed externally to the internal chamber formed between the baseplate body 112 and the baseplate shroud 104. The current carrying portions 116a-d may be received within the internal chamber.

The blades 114a-d are configured for connection to the meter mounting device. In use, when the electricity meter 100 is connected to the meter mounting device, the blades 114a-d are received by utility power line jaws of the meter mounting device (which are connected to the utility power line) and load jaws of the meter mounting device (which are connected to the load). In the exemplary arrangement shown in FIG. 2, the baseplate 102 comprises four blades. The two blades 114a, 114b are connected to corresponding utility power line jaws of the meter mounting device, and the two blades 114c, 114d are connected to corresponding load jaws of the meter mounting device.

The connection between the blades 114a-d and the utility power line and load jaws facilitates electricity flow from the utility power line and to the load via the utility power line jaws, the blades received by the utility power line jaws, the conductive body, the blades received by the load jaws and the load jaws. For example, the blade 114a may be received by a utility power line jaw of the meter mounting device and the blade 114c may be received by a load jaw of the meter mounting device. In this example, electricity flows from the utility power line to the load via the utility power line jaw, the blade 114a, the conductive bodies 116a and 116c, the blade 114c and the load jaw. Similarly, the blade 114b may be received by a utility power line jaw of the meter mounting device and the blade 114d may be received by a load jaw of the meter mounting device such that electricity flows from the utility power line and to the load via the utility power line jaw, the blade 114b, the conductive bodies 116b and 116d, the blade 114d and the load jaw.

The exemplary electricity meter 100 shown in FIGS. 1 and 2 is for connection to a typical ANSI 2S meter mounting device. The skilled person will appreciate that alternative electricity meters may be for connection to different meter mounting devices, and may comprise a different number and/or arrangement of blades, for example.

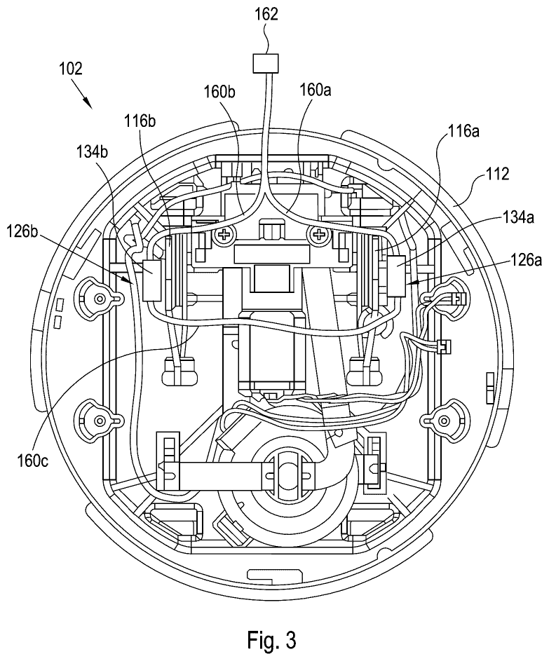

FIG. 3 shows a plan view of an exemplary baseplate 102. As can be seen in FIG. 3, the baseplate 102 comprises thermal devices 126a, 126b. The thermal devices 126a, 126b are mounted to the baseplate 102. In the specific example shown in FIG. 3, the thermal devices 126a, 126b are mounted to the baseplate body 112. The thermal devices 126a, 126b may be mounted in corresponding cavities formed in the baseplate body 112, for example, although the skilled person will appreciate that there are alternative ways that the thermal devices 126a, 126b may be mounted to the baseplate 102. The thermal devices 126a, 126b are electrically isolated from the utility service. For example, the thermal devices 126a, 126b may be mounted in corresponding non-conducting cavities. The skilled person will be familiar with alternative ways of electrically isolating components.

The thermal devices 126a, 126b may be mounted to the baseplate 102 such that when the baseplate 102 and baseplate shroud 104 are connected, the thermal devices 126a, 126b are located within the internal chamber formed between the baseplate body 112 and the baseplate shroud 104.

The thermal devices 126a, 126b are mounted in close proximity to respective blades 114a, 114b. In the exemplary arrangement shown in FIG. 3, the thermal device 126a is mounted such that it is located adjacent to the blade 114a and the thermal device 126b is mounted such that it is located adjacent to the blade 114b. The skilled person will appreciate that alternative arrangements may comprise a different number of thermal devices, for example alternative arrangements may comprise a single thermal device, or more than two thermal devices. Furthermore, the thermal device(s) may be located adjacent to alternative blades to those depicted in FIG. 3.

As described above, the at least a portion of the blades 114a, 114b (and in exemplary arrangements substantially all of the blades 114a, 114b) extend through respective apertures 120a, 120b in the baseplate body 112, such that the blades 114a, 114b are located externally to the internal chamber. Furthermore, the blades 114a, 114b extend from the conductive bodies 116a, 116b which are located within the internal chamber. In the exemplary arrangement of FIG. 3, the thermal devices 126a, 126b may be mounted adjacent to the conductive bodies 116a, 116b located within the internal chamber and from which the respective blades 114a, 114b extend. In exemplary arrangements, there may be no components located between the conductive bodies 116a, 116b and the thermal devices 126a, 126b, and in further exemplary arrangements, the thermal devices 126a, 126b may abut at least a portion of the conductive bodies 116a, 116b from which the respective blades 114a, 114b extend. Since the blades 114a, 114b and the conductive bodies 116a, 116b are good thermal conductors, the temperature of the conductive bodies 116a, 116b will be substantially the same as the temperature of blades 114a, 114b (which are in contact with the jaws of the meter mounting device).

As such, the thermal devices 126a, 126b are not separated from the blades 114a, 114b or the baseplate body 112 by the baseplate shroud 104, and therefore the overall thermal impedance between the jaws/blades connection and the thermal devices 126a, 126b is reduced. The thermal devices 126a, 126b therefore experience similar temperatures to those experienced by the baseplate 102 and the blades 114a, 114b.

In the exemplary arrangement shown in FIG. 3, the thermal devices 126a, 126b comprise thermal cut-off fuses. The thermal cut-off fuses form a circuit with another component of the electricity meter 100, and are configured to break (or open) the circuit when a temperature of one or both of the thermal cut-off fuses exceeds a temperature threshold. Exemplary thermal cut-off fuses may be those provided by Cantherm.

Each of the thermal cut-off fuses comprises a body 134a, 134b which comprises a thermal element located therein. In exemplary arrangements, the bodies 134a, 134b of the thermal cut-off fuses are mounted adjacent to respective blades 114a, 114b, and in the specific example shown in FIG. 3, the bodies 134a, 134b are mounted adjacent to the conductive bodies 116a, 116b from which the respective blades 114a, 114b extend. The thermal element is configured to melt when it reaches the temperature threshold, thereby breaking the circuit. The thermal cut-off fuses may be single-use. The skilled person will be familiar with the operation of thermal cut-off fuses, and further detail is not provided here.

The skilled person will appreciate that in alternative arrangements, alternative thermal devices may be mounted to the baseplate 102 such that they are located within the internal chamber formed between the baseplate body 112 and the baseplate shroud 104. For example, in alternative arrangements, the thermal device(s) 126a, 126b may comprise thermal cut-off switches configured to break (or open) the circuit when a threshold temperature is exceeded and re-close the circuit when the temperature drops below the threshold temperature. In further alternative arrangements, the thermal device(s) may comprise a temperature sensor configured to collect data indicative of the temperature of the blades and transmit the data to the electricity meter electronics 106 for processing and determination of whether a temperature threshold has been exceeded. The skilled person will be able to envisage other arrangements.

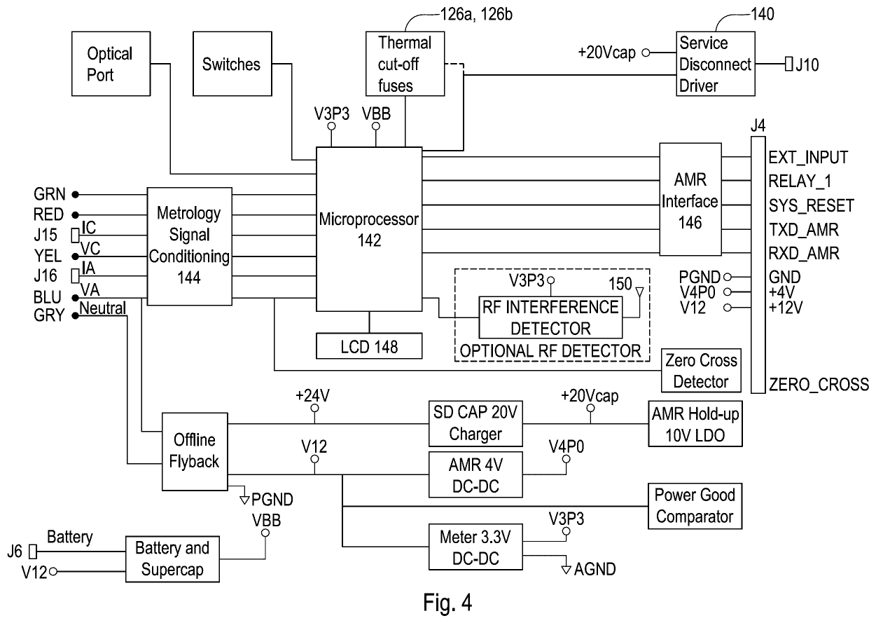

The electricity meter 100 further comprises a service switch 140, or a service disconnect driver/relay, as shown in FIG. 4, which is a schematic block diagram of electrical components of the electricity meter 100. The service switch 140 may be mounted to the baseplate 102, and as such may be received within the internal chamber formed between the baseplate body 112 and the baseplate shroud 104. When the electricity meter 100 is connected to the meter mounting device, the service switch 140 is configured to enable the electrical connection between the utility power line and the electricity meter 100 when closed, and disable the electrical connection between the utility power line and the electricity meter 100 when open. The service switch 140 may be controllable by thermal devices 126a, 126b via the electricity meter electronics 106, and specifically a microprocessor 142 of the electricity meter electronics 106.

The electricity meter electronics 106 may be configured to determine power consumption between the utility power line and the load. In addition to the microprocessor 142, the electricity meter electronics 106 may further comprise one or more of: a metrology circuit/signal conditioning module 144, an AMR Interface 146, an LCD or other display 148 and optionally, an RF interference detector 150. In contrast to the thermal devices 126a, 126b, which as described above are mounted in the internal chamber formed between the baseplate 102 and the baseplate shroud 104, the electricity meter electronics 106 may be mounted within the electronics housing 108. As such, the electricity meter electronics 106 may be separated from the baseplate 102 by the baseplate shroud 104.

As shown in FIG. 4, the thermal devices 126a, 126b are electrically connected to the electricity meter electronics 106, and specifically the microprocessor 142. In the exemplary arrangement shown in FIGS. 1-4, the thermal devices 126a, 126b form a circuit with the microprocessor 142 of the electricity meter electronics 106.

As shown in FIG. 3, the thermal devices 126a, 126b (which in this particular example comprise thermal cut-off fuses) are electrically connected in series, via leads/wires 160a-c. In the exemplary arrangement of FIG. 3, the leads 160a, 160b terminate in a connector 162 configured for electrical connection to the electricity meter electronics 106, specifically the microprocessor 142. The thermal devices 126a, 126b may be connected to the microprocessor 142 through a pull up resistor connected to a V3P3 (3.3 VDC DC power supply). The skilled person will appreciate that such a connection is exemplary only and will be able to envisage other ways that the thermal devices 126a, 126b may be connected to the microprocessor 142. The microprocessor 142 is electrically connected to and in communication with the service switch 140.

In alternative arrangements, the thermal devices 126a, 126b may be directly connected to the service switch 140. That is, the thermal devices 126a, 126b may form a circuit with the service switch 140 and not the microprocessor 142, illustrated by the dashed line between the thermal devices 126a, 126b and the service switch 140 in FIG. 4.

Use of the electricity meter 100 to provide an early detection of an adverse thermal event at the baseplate 102 is described below, with reference to FIGS. 1-4.

In use, the electricity meter 100 is connected to the utility power line and the load of a residence/building via the meter mounting device. The electricity meter 100 is mounted to the meter mounting device by engaging the blades 114a-d of the baseplate 102 with the corresponding jaws of the meter mounting device. Electricity from the utility power line flows to the load via the electricity meter 100 due to the connection between the blades 114a-d of the baseplate 102 and the jaws of the meter mounting device, as described above.

In one exemplary arrangement, the thermal devices 126a, 126b comprise thermal cut-off fuses which form a circuit with the microprocessor 142. During operation of the electricity meter 100, if the circuit formed between the thermal cut-off fuses and the microprocessor 142 is closed, the microprocessor 142 is configured to control the service switch 140 to operate in a closed position, such that the electrical connection between the utility power line and the electricity meter 100 is enabled. When the service switch 140 is in the closed position, electricity flows through the electricity meter from the utility power line and to the load.

The circuit formed by the thermal cut-off fuses with the microprocessor 142 remains closed if the temperature of the thermal cut-off fuses, and specifically the thermal elements within the thermal cut-off fuses, does not exceed the temperature threshold.

The skilled person will appreciate that the temperatures of the thermal cut-off fuses are indicative of the temperature of the baseplate 102 and/or blades 114a, 114b. As such, the temperature threshold of the thermal devices 126a, 126b (in this example thermal cut-off fuses) may be selected to be lower than a temperature at which irreversible damage to the baseplate 102, or other components of the electricity meter 100, may occur. For example, typically, the baseplate body 112 is formed of a plastic material, which in one particular example may be a polycarbonate resin such as LEXAN™ 500R, which may have a melting point of approximately 150° C. In this particular example, the temperature threshold may be one or more of: substantially 110° C., substantially 120° C., substantially 130° C., and substantially 140° C. The skilled person will appreciate that the baseplate may be formed of alternative materials comprising alternative melting points, and the temperature threshold may be selected accordingly. As long as the temperature of the thermal devices 126a, 126b remains below the temperature threshold, the circuit formed between the microprocessor 142 and the thermal cut-off fuses remains closed, and the service switch 140 remains in the closed position.

Over the life of the electricity meter 100 and the meter mounting device, the jaws of the meter mounting device and/or the blades 114a-d of the electricity meter 100 may degrade. For example, due to adverse weather conditions experienced, or from repeated connection and disconnection of the blades 114a-d of the electricity meter 100 with the jaws of the meter mounting device. Due to this degradation, resistance may be introduced at the connection between the blades 114a-d and the jaws, and the temperature at the connection may begin to increase.

As the temperature of the connection between the blades 114a-d and the jaws increases, the temperature of the thermal cut-off fuses also increases. Because the thermal cut-off fuses are in close proximity to the blades 114a, 114b, due to the thermal cut-off fuses being mounted to the baseplate 102 and adjacent to the blades 114a, 114b, the temperature increases experienced by the blades 114a, 114b translate into temperature increases of the thermal cut-off fuses with minimal delay. The temperature increase of the thermal cut-off fuses occurs with minimal delay because the thermal cut-off fuses are not physically separated from the connection between the blades 114a-d and the jaws by multiple shrouds, including the baseplate shroud 104.

If the increase in temperature at the blade/jaw connection causes the temperature of one or both of the thermal cut-off fuses to exceed the threshold temperature, the circuit formed between the thermal cut-off fuses and the microprocessor 142 is broken.

The microprocessor 142 is configured to control the service switch 140 to disable the electrical connection between the utility power line and the electricity meter 100, if the circuit formed between the thermal cut-off fuses and the microprocessor 142 is broken. As such, all of the service load from the utility power line is removed from electricity meter 100 and the meter mounting device.

As mentioned above, because the temperature threshold of the thermal devices 126a, 126b is set to be lower than a temperature at which irreversible damage to the baseplate 102, or other components of the electricity meter 100 may occur, the thermal cut-off fuse may break the circuit, and the service load from the utility power line may be removed, before such irreversible structural damage occurs. Therefore, in the event of an adverse temperature event, the only component of the electricity meter 100 that would need to be replaced would be the thermal cut-off fuse(s) and not the entire baseplate.

The microprocessor 142 may be further configured to control a transmitter of the electricity meter 100 to transmit an alarm signal if the circuit formed by the thermal cut-off fuses is broken. The alarm signal may be transmitted to a utility control centre, for example, to indicate that an adverse temperature event has occurred and a service visit to the site of the electricity meter 100 and the meter mounting device is required.

The above operation is described with reference to an electricity meter 100 comprising thermal devices 126a, 126b comprising thermal cut-off fuses. The skilled person will appreciate that in alternative arrangements, the thermal devices 126a, 126b may comprise thermal cut-off switches, which operate similarly to the thermal-cut off fuses described above, but are configured to re-close the circuit once the temperature of the thermal element therein drops below the threshold temperature. In further alternative arrangements, the thermal devices 126a, 126b may comprise temperature sensors mounted adjacent to the blades and configured to transmit temperature data to the microprocessor 142. The microprocessor 142 may be configured to disable the electrical connection between the utility power line and the electricity meter 100 if the temperature data received indicates that the temperature at the temperature sensors exceeds the threshold. The skilled person will appreciate that alternative temperature or heat devices may also be used.

It will be appreciated by the person of skill in the art that various modifications may be made to the above described embodiments without departing from the scope of the invention.

1. An electricity meter for connection to a utility power line and a load via a meter mounting device and for determining power consumption between the utility power line and the load, the electricity meter comprising:
a baseplate comprising at least one blade configured to couple to a corresponding jaw of the meter mounting device to electrically connect the electricity meter to the utility power line and the load;
a service switch operable to enable or disable the electrical connection between the utility power line and the electricity meter,
wherein the baseplate further comprises a thermal device located adjacent to the at least one blade and configured to control the service switch to disable the electrical connection between the utility power line and the electricity meter if a temperature of the thermal device exceeds a temperature threshold.

2. An electricity meter according to claim 1, wherein the thermal device is mounted to the baseplate.

3. An electricity meter according to claim 1, further comprising a baseplate shroud connected to the baseplate, and wherein the thermal device is located in an internal chamber formed between the baseplate and the baseplate shroud.

4. An electricity meter according to claim 3, wherein the service switch is located in the internal chamber.

5. An electricity meter according to claim 1, further comprising a conductive body, wherein the at least one blade extends from the conductive body, and wherein the thermal device is located adjacent to the conductive body.

6. An electricity meter according to claim 5, further comprising a baseplate shroud connected to the baseplate, and wherein the thermal device is located in an internal chamber formed between the baseplate and the baseplate shroud, and wherein the conductive body is located in the internal chamber and wherein the at least one blade is located externally to the internal chamber.

7. An electricity meter according to claim 1, wherein the thermal device forms part of a circuit, and wherein the thermal device is configured to break the circuit when the temperature of the thermal device exceeds the temperature threshold.

8. An electricity meter according to claim 7, wherein the service switch is controlled to enable the electrical connection between the utility power line and the electricity meter when the circuit is closed and disable the electrical connection between the utility power line and the electricity meter when the circuit is broken.

9. An electricity meter according to claim 7, further comprising electricity meter electronics comprising a microprocessor, and wherein the thermal device forms the circuit with the microprocessor.

10. An electricity meter according to claim 9, wherein if the circuit between the microprocessor and the thermal device is broken, the microprocessor is configured to control the service switch to disable the electrical connection between the utility power line and the electricity meter.

11. An electricity meter according to claim 9, further comprising a baseplate shroud connected to the baseplate, and wherein the thermal device is located in an internal chamber formed between the baseplate and the baseplate shroud, and wherein the electricity meter electronics are separated from the thermal device by the baseplate shroud.

12. An electricity meter according to claim 7, wherein the thermal device forms a circuit with the service switch, and wherein the service switch is configured to disable the electrical connection between the utility power line and the electricity meter if the circuit is broken.

13. An electricity meter according to claim 1, wherein the baseplate comprises first and second blades, a first thermal device located adjacent to the first blade, and a second thermal device located adjacent to the second blade.

14. An electricity meter according to claim 13, wherein the first and second thermal devices are mounted to the baseplate.

15. An electricity meter according to claim 1, wherein the thermal device comprises a thermal cut-off fuse or thermal switch.

16. A baseplate for an electricity meter, the electricity meter for connection to a utility power line and a load via a meter mounting device and for determining power consumption between the utility power line and the load, the baseplate comprising:
at least one blade configured to couple to a corresponding jaw of the meter mounting device to electrically connect the electricity meter to the utility power line and the load; and
a thermal device located adjacent to the at least one blade and configured to control a service switch to disable the electrical connection between the utility power line and the electricity meter if a temperature of the thermal device exceeds a temperature threshold.
